(19) United States
(12) Patent Application Publication
(10) Pub. No.: US 2013/0033281 A1
(43) Pub. Date: Feb. 7, 2013

(54) PROBE ASSEMBLY

(71) Applicants: BO TIAN, Shenzhen City (CN); GUO-YI CHEN, Shenzhen City (CN)

(72) Inventors: BO TIAN, Shenzhen City (CN); GUO-YI CHEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/233,914

(22) Filed: Sep. 15, 2011

(30) Foreign Application Priority Data
Aug. 1, 2011 (CN) 201120275982.7

(51) Int. Cl. G01R 1/067

(52) U.S. Cl. 324/755.01

(57) ABSTRACT

A probe assembly includes a probe, a transducer, and a cable electronically connecting the probe with the transducer. The cable has a jacket made of an extreme-environment resistant material.

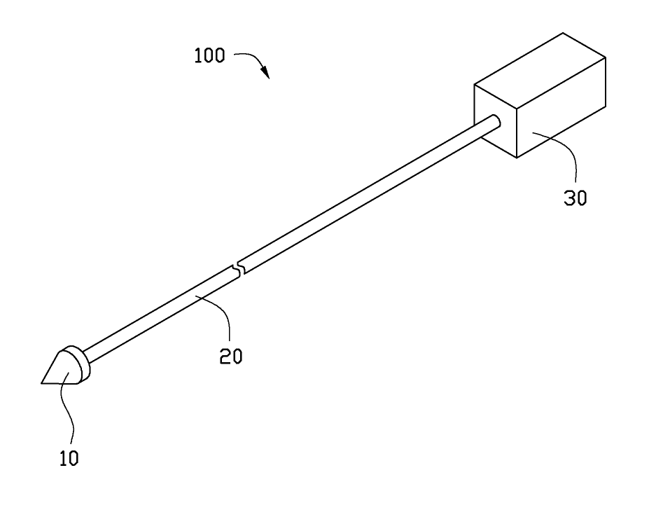

### BACKGROUND

1. Technical Field

The present disclosure relates to probe assemblies, particularly to a probe assembly to be used for oscillographs.

2. Description of Related Art

Oscillographs are often used for testing circuit boards of electronic devices. Sometimes, an external environment, such as a high temperature environment and/or a high humidity environment needs to be simulated to test a reliability of the circuit board. A probe assembly commonly used to connect to the circuit boards is partially positioned in the simulated environment. Therefore, a jacket of a cable of the probe assembly is affected by the simulated environment. As a result, a life of the probes will be shortened.

Therefore, there is room for improvement within the art.

### BRIEF DESCRIPTION OF THE DRAWING

Many aspects of the present embodiments can be better understood with reference to the following drawing. The components in the drawing are not necessarily drawn to scale, the emphasis instead being placed upon clearly illustrating the principles of the present probe assembly. Moreover, in the drawing, the view is schematic.

The FIGURE is an isometric view of a probe assembly of an oscillograph in accordance with an exemplary embodiment.

### DETAILED DESCRIPTION

The disclosure, including the accompanying drawing, is illustrated by way of example and not by way of limitation. It should be noted that references to “an” or “one” embodiment in this disclosure are not necessarily to the same embodiment, and such references mean at least one.

Referring to the FIGURE, an exemplary embodiment of a probe assembly 100 of an oscillograph (not shown) includes a tapered probe 10, a cable 20, and a transducer 30.

The probe 10 is configured to connect to an object under test for gathering sampling signals of the object under test (not shown). In the exemplary embodiment, the probe 10 can be detachably contacted with or welded to a probe point of the object under test.

The cable 20 electronically connects the probe 10 with the transducer 30, for transmitting the sampling signals gathered by the probe 10 to the transducer 30. A jacket of the cable 20 is made of materials resistant to extreme conditions, such as high temperatures and/or high humidity to prevent the cable 20 from damage when the probe assembly 10 is used in a high temperature environment and/or high humidity environment. The jacket of the cable 20 can be made of polyvinylchloride (PVC).

The transducer 30 is electronically connected to the oscillograph. The transducer 30 processes, such as filters and reshapes the sampling signals gathered by the probe 10, and transmits the processed sampling signals to the oscillograph.

In use, even the probe assembly 100 is used in a high temperature environment and/or high humidity environment, since the jacket of the cable 20 is made of high temperature-proof material and/or high humidity-proof material, such as PVC, the cable 20 can be prevented from damage by high temperature and/or high humidity. Therefore, the life of the probe assembly 100 will be extended.

It is to be understood, however, that even through numerous characteristics and advantages of the present disclosure have been set forth in the foregoing description, together with details of assembly and function, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A probe assembly comprising:
a transducer;
a probe; and
a cable connected the transducer with the probe, and having a jacket made of an extreme-environment resistant material.

2. The probe assembly as claimed in claim 1, wherein the extreme-environment resistant material comprises a high temperature-proof material and/or high humidity-proof material.

3. The probe assembly as claimed in claim 1, wherein the jacket of the cable is made of polyvinylchloride.

4. The probe assembly as claimed in claim 1, wherein the probe is detachably contacted with or welded to a probe point of an object under test.
